(19) United States
(12) Patent Application Publication
(10) Pub. No.: US 2008/0085584 A1
(43) Pub. Date: Apr. 10, 2008

(54) OXIDATION/HEAT TREATMENT METHODS OF MANUFACTURING NON-VOLATILE MEMORY DEVICES

(75) Inventors: Young-Jin Noh, Suwon-si (KR); Chul-Sung Kim, Seongnam-si (KR); Si-Young Choi, Seongnam-si (KR); Bon-Young Koo, Suwon-si (KR); Ki-Hyun Hwang, Seongnam-si (KR); Sung-Kweon Baek, Suwon-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/857,824

(22) Filed: Sep. 19, 2007

(30) Foreign Application Priority Data
Oct. 4, 2006 (KR) 10-2006-0097491

(51) Int. Cl. H01L 21/336

(52) U.S. Cl. 438/264; 257/E21.409

(57) ABSTRACT

Methods of manufacturing non-volatile memory devices are disclosed which may at least partially cure etch damage and may at least partially remove defect sites in gate structures of the devices caused during manufacturing of the devices. An exemplary method of manufacturing a non-volatile memory device includes forming a gate structure on a substrate, the gate structure including a control gate electrode, a blocking layer pattern, a floating gate electrode, and a tunnel insulating layer pattern. An oxidation process is performed that at least partially cures damage caused to the substrate and to the gate structure during formation of the gate structure. A first heat treatment is performed under a gas atmosphere including nitrogen to at least partially remove defect sites on the gate structure caused by the oxidation process. A second heat treatment is performed under a gas atmosphere including chlorine to at least partially remove remaining defect sites on the gate structure caused by the oxidation process.

### CROSS-REFERENCE TO RELATED APPLICATIONS

This application claims priority under 35 USC § 119 to Korean Patent Application No. 2006-97491, filed on Oct. 4, 2006 in the Korean Intellectual Property Office, the contents of which are incorporated herein by reference in their entirety.

### BACKGROUND OF THE INVENTION

1. Field of the Invention

The present invention relates to methods of manufacturing semiconductor devices and, more particularly, to methods of manufacturing non-volatile memory devices with floating gate electrodes.

2. Description of the Related Art

Semiconductor memory devices, in general, are classified as either volatile or non-volatile type semiconductor memory devices. Volatile semiconductor memory devices, such as dynamic random-access memory (DRAM) devices and static random-access memory (SRAM) devices, can have relatively high input/output (I/O) speeds. However, volatile semiconductor memory devices lose data stored therein when power is shut-off. In contrast, non-volatile semiconductor memory devices, such as electrically erasable programmable read-only memory (EEPROM) devices and flash memory devices, can have relatively slow I/O speeds but maintain data stored therein when power is shut-off.

In EEPROM devices, data is electrically stored, i.e., programmed or erased, through a Fowler-Nordheim (F—N) tunneling mechanism and/or a channel hot electron injection mechanism. Flash memory devices can be classified as either floating gate type or charge trap type devices, and include silicon-oxide-nitride-oxide-semiconductor (SONOS) type devices and metal-oxide-nitride-oxide-semiconductor (MONOS) type devices.

A floating gate type non-volatile memory device includes a gate structure and source/drain regions. The gate structure includes a tunnel insulating layer pattern, a floating gate electrode, a blocking layer pattern and a control gate electrode. A silicon oxide layer pattern, which is formed by a thermal oxidation process, may be used as the tunnel insulating layer pattern. A multi-layered dielectric layer pattern, which includes a lower silicon oxide layer pattern, a silicon nitride layer pattern and an upper silicon oxide layer pattern, may be used as the blocking layer pattern. Each of the floating and control gate electrodes may include polysilicon doped with impurities.

A reactive ion etch (RIE) process may be carried out to form the gate structure. Because the RIE process may damage the gate structure, a re-oxidation process may be performed in an attempt to cure such damage. For example, surface portions of the floating gate electrode and the control gate electrode may be sufficiently re-oxidized during the re-oxidation process to sufficiently cure damage thereto caused by the RIE process. However, the re-oxidation process may cause formation of a bird's beak phenomenon at edge portions of the tunnel insulating layer pattern, which may deteriorate electrical characteristics of the tunnel insulating layer pattern. In contrast, when the re-oxidation process is not sufficiently performed to reoxidize the floating gate electrode and the control gate electrode, defect sites may remain in the gate structure and deteriorate the reliability of the non-volatile memory device.

### SUMMARY OF THE INVENTION

Various embodiments of the present invention are directed to methods of manufacturing non-volatile memory devices which may at least partially cure etch damage and may at least partially remove defect sites in gate structures of the devices caused during manufacturing of the devices.

In some embodiments of the present invention, a method of manufacturing a non-volatile memory device includes forming a gate structure on a substrate, the gate structure including a control gate electrode, a blocking layer pattern, a floating gate electrode, and a tunnel insulating layer pattern. An oxidation process is performed that at least partially cures damage caused to the substrate and to the gate structure during formation of the gate structure. A first heat treatment is performed under a gas atmosphere including nitrogen to at least partially remove defect sites on the gate structure caused by the oxidation process. A second heat treatment is performed under a gas atmosphere including chlorine to at least partially remove remaining defect sites on the gate structure caused by the oxidation process.

In some further embodiments, the oxidation process is at least partially performed using oxygen radicals.

In some further embodiments, the oxidation process is at least partially performed at one or more temperatures within a range between about 800° C. to about 1,100° C.

In some further embodiments, the oxidation process is at least partially performed using a reactive gas including oxygen (O₂) and hydrogen (H₂), and a flow rate of the hydrogen (H₂) during the oxidation process may be between about 10 percent to about 33 percent of a flow rate of the reactive gas.

In some further embodiments, the oxidation process is at least partially performed using at least one selected from the group consisting of oxygen (O₂), ozone (O₃), and water vapor (H₂O).

In some further embodiments, the first heat treatment is at least partially performed under a gas atmosphere including at least one selected from the group consisting of nitrogen (N₂), nitrogen monoxide (NO), nitrous oxide (N₂O), and ammonia (NH₃). The first heat treatment may be at least partially carried out using a reactive gas including nitrogen (N2) and nitrogen monoxide (NO). A flow rate of the nitrogen monoxide (NO) during the first heat treatment may be about 1 percent to about 20 percent of a flow rate of the reactive gas.

In some further embodiments, the first heat treatment is at least partially performed at one or more temperatures within a range between about 800° C. to about 1,100° C.

In some further embodiments, the second heat treatment is at least partially performed under a gas atmosphere including hydrogen chloride (HCl) and at least one selected from the group consisting of oxygen (O₂), ozone (O₃), and water vapor (H₂O). The second heat treatment may be at least partially performed using a reactive gas including hydrogen chloride (HCl) and oxygen (O₂). A flow rate of the hydrogen chloride (HCl) may be about 0.1 percent to about 10 percent of a flow rate of the reactive gas.

In some further embodiments, the second heat treatment is at least partially performed at one or more temperatures within a range between about 800° C. to about 1,100° C.

In some further embodiments, the oxidation process and the first heat treatment are performed in-situ within a chamber without breaking vacuum seal of the chamber.

In some further embodiments, the first and second heat treatments are performed in-situ within a chamber without breaking vacuum seal of the chamber.

In some further embodiments, the oxidation process and the first and second heat treatments are performed in-situ within a chamber without breaking vacuum seal of the chamber.

In some further embodiments, the blocking layer pattern is formed to include a lower dielectric layer, a middle dielectric layer, and an upper dielectric layer. Each of the lower and upper dielectric layers may be formed to include silicon oxide, and the middle dielectric layer may be formed to include silicon nitride or to include metal oxide having a dielectric constant higher than that of silicon nitride. The metal oxide may include at least one selected from the group consisting of hafnium (Hf), zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

### BRIEF DESCRIPTION OF THE DRAWINGS

Example embodiments of the present invention will become readily apparent along with the following detailed description when considered in conjunction with the accompanying drawings, wherein:

FIGS. 1 to 11 are cross-sectional views illustrating methods of manufacturing a non-volatile memory device according to some embodiments of the present invention;

FIG. 12 is a graph illustrating high-temperature stress (HTS) characteristics that were determined by experimentation on a first non-volatile memory device manufactured by a conventional process and experimentation on a second non-volatile memory device manufactured by methods according to some embodiments of the present invention; and

FIG. 13 is a graph illustrating read disturbances that were determined by experimentation on a first non-volatile memory device manufactured by a conventional process and experimentation on a second non-volatile memory device manufactured by methods according to some embodiments of the present invention.

### DESCRIPTION OF THE EMBODIMENTS

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

FIGS. 1 to 11 are cross-sectional views illustrating methods of manufacturing a non-volatile memory device according to some embodiments of the present invention.

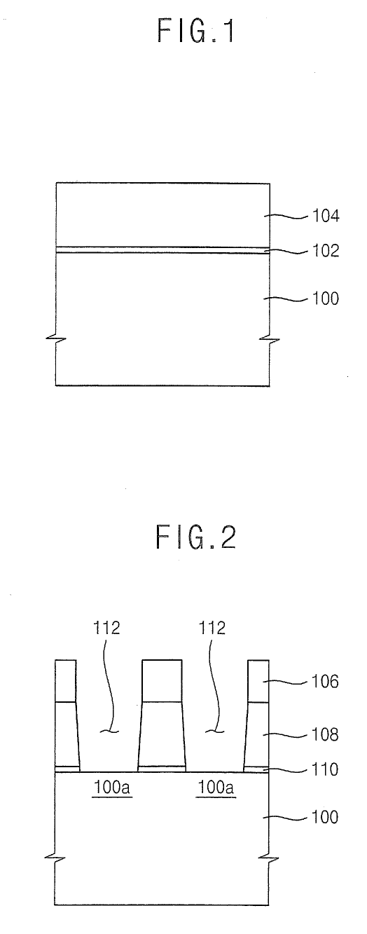

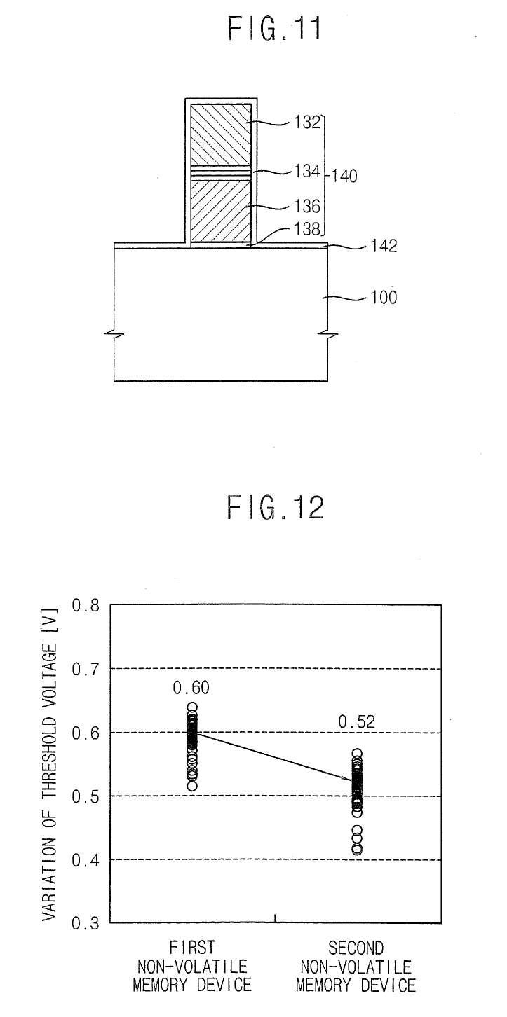

FIGS. 2 to 9 are cross-sectional views taken along a word line of the non-volatile memory device, and FIGS. 10 and 11 are cross-sectional views taken along a field insulating pattern of the non-volatile memory device.

Referring to FIG. 1, a pad oxide layer 102 may be formed on a substrate 100, such as a silicon wafer and semiconductor substrate, and a mask layer 104 may then be formed on the pad oxide layer 102.

The pad oxide layer 102 may be formed by a thermal oxidation process or a chemical vapor deposition (CVD) process to have thickness in a range of about 70 Å to about 100 Å. The pad oxide layer 102 may be formed at a temperature of about 750° C. to about 900° C. for a surface treatment of the substrate 100.

The mask layer 104 may include silicon nitride and may be formed to a thickness of about 1,500 Å by a low pressure chemical vapor deposition (LPCVD) process or a plasma-enhanced chemical vapor deposition (PECVD) process using dichlorosilane (SiH₂Cl₂), silane (SiH₄), ammonia (NH₃), etc.

Referring to FIG. 2, photoresist patterns 106 that partially expose surface portions of the mask layer 104 may be formed on the mask layer 104 by a photolithography process. The exposed portions of the mask layer 104 and the pad oxide layer 102 may be sequentially etched away by an etching process using the photoresist patterns 106 as etching masks, thereby forming mask patterns 108 and pad oxide patterns 110 on the substrate 100. The mask patterns 108 and the pad oxide patterns 110 are formed to define first openings 112, which expose isolation regions 100a of the substrate 100.

For example, the exposed portions of the mask layer 104 and the pad oxide layer 102 may be etched away by a dry etching process using plasma or a reactive ion etching process. The photoresist patterns 106 may be removed by ashing and/or stripping processes after forming the mask patterns 108 and the pad oxide patterns 110.

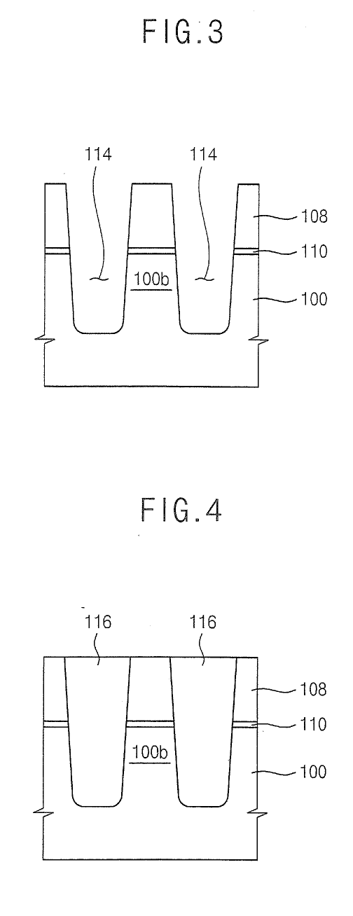

Referring to FIG. 3, an etching process using the mask patterns 108 as etching masks may be performed to etch away the exposed portions of the isolation regions 100a of the substrate 100, thereby forming trenches 114 extending in a first direction across the substrate 100. The trenches 114 may be formed to a depth of about 1,000 Å to about 5,000 Å from an upper surface of the substrate 100.

A thermal oxidation process may be performed on sidewalls of the trenches 114 to at least partially cure silicon damage caused during the etching process for forming the trenches 114 by impinging high energy ions, and to reduce/prevent leakage current from flowing through the sidewalls of the trenches 114. Trench oxide layers (not shown) may be formed to have thickness in a range of about 50 Å to about 250 Å on inner surfaces of the trenches 114 during the thermal oxidation process.

Liner nitride layers (not shown) may be formed to have thickness in a range of about 50 Å to about 100 Å on the trench oxide layers. Such liner nitride layers may substantially reduce/prevent diffusion of impurities (e.g., carbon and hydrogen) from a subsequently formed trench-filling layer, e.g., a field insulating layer, into active regions 100b defined by the trenches 114.

According to another example embodiment of the present invention, the trenches 114 may be formed by an etching process using the photoresist patterns 106 as etching masks.

Referring to FIG. 4, a field insulating layer (not shown) may be formed on the substrate 100 so as to at least partially fill the trenches 114. The field insulating layer may include silicon oxide, such as undoped silicate glass (USG), tetraethyl orthosilicate (TEOS), high-density plasma (HDP)-CVD oxide, and the like, which can be used alone or in combinations thereof. For example, the field insulating layer may be formed by an HDP-CVD process using silane (SiH₄), oxygen (O₂), and argon (Ar) as plasma source gases.

A planarization process, such as a chemical mechanical polishing (CMP) process, may be performed to remove an upper portion of the field insulating layer until the mask patterns 108 are exposed, thereby forming field insulating patterns 116 in the trenches 114. The field insulating patterns 116 may serve as isolation layer patterns and may define the active regions 100b of the substrate 100. Though not shown in the figures, the mask patterns 108 may be partially removed during the planarization process.

Referring to FIG. 5, the mask patterns 108 and the pad oxide layer patterns 110 may be removed to form second openings 118 exposing the active regions 100b of the substrate 100. For example, the mask patterns 108 may be removed by an etching solution including phosphoric acid, and the pad oxide layer patterns 110 may be removed by a diluted hydrofluoric acid solution. As shown in the figures, the field insulating patterns 116 may be partially removed while the mask patterns 108 and the pad oxide layer patterns 110 are removed.

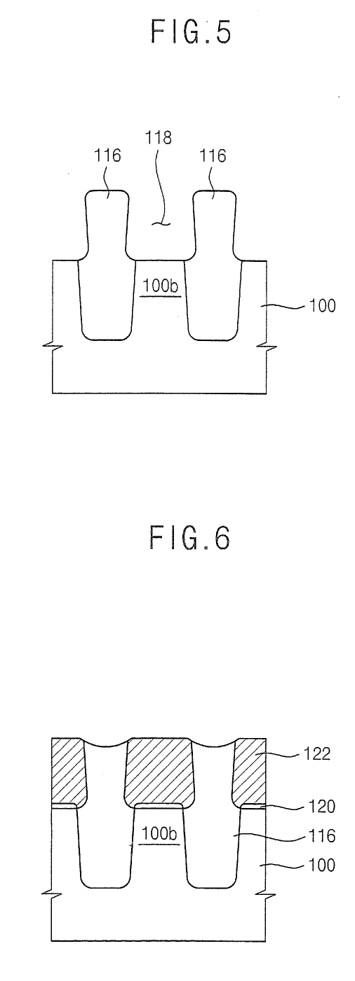

Referring to FIG. 6, a tunnel insulating layer 120 may be formed on the exposed active regions 100b. The tunnel insulating layer 120 may include silicon oxide. For example, the tunnel insulating layer 120 may be formed to have thickness in a range of about 30 Å to about 150 Å on the active regions 100b by a thermal oxidation process.

A floating gate conductive layer (not shown) may be formed on the tunnel insulating layer 120 and the field insulating patterns 116. The floating gate conductive layer may include impurity-doped polysilicon and may be formed at a temperature of about 580° C. to about 620° C. using SiH₄ gas and PH₃ gas.

After forming the floating gate conductive layer, a planarization process, such as a CMP process or an etch-back process, may be performed until the field insulating patterns 116 are exposed, thereby forming floating gate patterns 122 in the second openings 118. The field insulating patterns 116 may be partially removed during the planarization process.

In accordance with another example embodiment of the present invention, floating gate patterns may be formed by forming a tunnel insulating layer and a floating gate conductive layer and then patterning the floating gate conductive layer.

In particular, in accordance with another example embodiment of the present invention, a tunnel insulating layer and a floating gate conductive layer may be formed on a semiconductor substrate. Mask patterns including oxide or nitride may be formed on the floating gate conductive layer, and an anisotropic etching process using the mask patterns as etching masks may be performed to form trenches in the semiconductor substrate so that floating gate patterns, tunnel insulating layer patterns, and active regions are defined by the trenches. A field insulating layer may be formed to fill up the trenches, and a CMP process may be performed to remove an upper portion of the field insulating layer until the floating gate patterns are exposed.

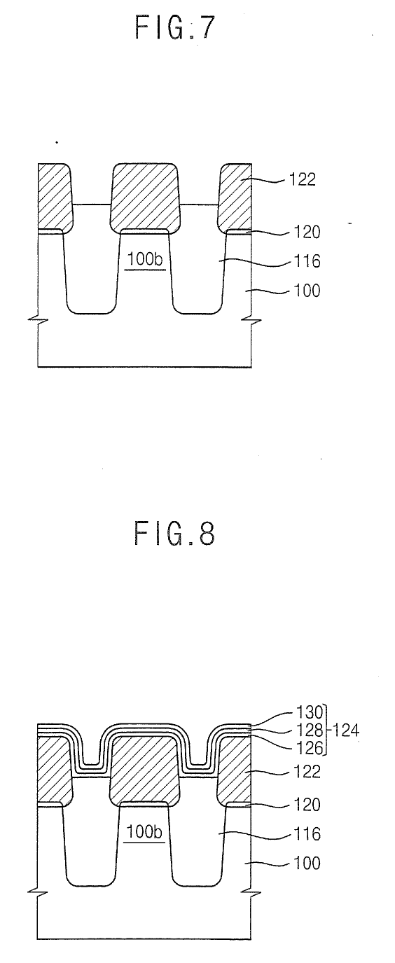

Referring to FIG. 7, upper portions of the field insulating patterns 116 may be removed (i.e., recessed) to expose upper sidewall portions of the floating gate patterns 122. The upper portions of the field insulating patterns 116 may be removed by an anisotropic and/or isotropic etching process. While removing the upper portions of the field insulating patterns 116, it is desirable that the etching process be performed so as not to expose the tunnel insulating layer 120 on the active regions 100b, otherwise, the etching solution or the etching gas can damage the tunnel insulating layer 120. Further, while removing the upper portions of the field insulating patterns 116, the floating gate patterns 122 may be partially removed such that corner portions thereof may become rounded.

Referring to FIG. 8, a blocking layer 124 may be formed on the floating gate patterns 122 and the field insulating patterns 116. The blocking layer 124 may include a lower silicon oxide layer 126, a silicon nitride layer 128, and an upper silicon oxide layer 130.

The lower silicon oxide layer 126 may be formed to have thickness in a range of about 30 Å to about 150 Å on the floating gate patterns 122 and the field insulating patterns 116 by a middle temperature oxide (MTO) deposition process and/or an HDP deposition process.

The silicon nitride layer 128 may be formed to have thickness in a range of about 30 Å to about 150 Å on the lower silicon oxide layer 126 by an LPCVD process.

The upper silicon oxide layer 130 may be formed to have thickness in range of about 30 Å to about 150 Å on the silicon nitride layer 128 by an MTO deposition process and/or a HDP deposition process.

In accordance with another example embodiment of the present invention, the silicon nitride layer 128 may be replaced by a metal oxide layer, so that the blocking layer 124 may have a stacked structure including the lower silicon oxide layer 126, a metal oxide layer, and the upper silicon oxide layer 130. The metal oxide layer may have a dielectric constant higher than that of silicon nitride, and may be formed to have thickness in a range of about 20 Å to about 100 Å by an atomic layer deposition (ALD) process and/or a CVD process. Examples of a metal that may be used for the metal oxide layer may include, but are not limited to, hafnium (Hf), zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), and the like, and which may be used alone or in a combination thereof. For example, the metal oxide layer may include hafnium oxide (HfO₂), zirconium oxide (ZrO₂), aluminum oxide (Al₂O₃), hafnium aluminum oxide (HfAlO), lanthanum oxide (La₂O₃), hafnium lanthanum oxide (HfLaO), aluminum lanthanum oxide (AlLaO), etc.

Alternatively, in accordance with still another example embodiment of the present invention, the blocking layer 124 may include a lower dielectric layer, a middle dielectric layer, and an upper dielectric layer. The middle dielectric layer may include a material having an energy band gap smaller than that of the lower dielectric layer, and the upper dielectric layer may include a material substantially identical to that of the lower dielectric layer. For example, the lower dielectric layer may include aluminum oxide and the middle dielectric layer may include hafnium oxide or zirconium oxide.

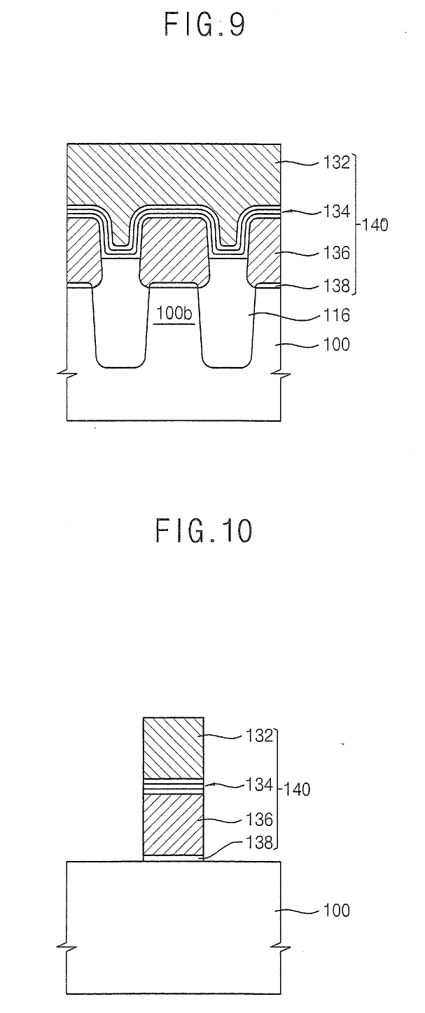

Referring to FIGS. 9 and 10, a control gate conductive layer (not shown) may be formed on the blocking layer 124. Examples of a material that may be used for the control gate conductive layer may include impurity-doped polysilicon, a metal, a metal silicide, and the like. For example, the control gate conductive layer may include an impurity-doped polysilicon layer and a metal layer, or a metal silicide layer formed on the impurity-doped polysilicon layer. The metal layer may include tungsten. Examples of the metal silicide may include tungsten silicide (WSi), titanium silicide (TiSi), cobalt silicide (CoSi), tantalum silicide (TaSi), etc.

In accordance with another example embodiment of the present invention, the control gate conductive layer may include an impurity-doped polysilicon layer, an ohmic layer, a metal barrier layer, and a metal layer. A metal silicide layer may be used as the ohmic layer, and a metal nitride layer may be used as the metal barrier layer.

The control gate conductive layer, the blocking layer 124, the floating gate patterns 122 and the tunnel insulating layer 120 may be patterned to form a gate structure 140 on the active regions 100b of the substrate 100, which extends in a second direction different from the first direction. For example, the second direction can be substantially perpendicular to the first direction. The patterning process for forming the gate structure 140 may be performed until the active regions 100b are exposed.

The gate structure 140 may include a control gate electrode 132 (formed from the control gate conductive layer), a blocking layer pattern 134, a floating gate electrode 136 and a tunnel insulating layer pattern 138. The control gate electrode 132 may include a polysilicon layer pattern and a metal layer pattern. The metal layer pattern may serve as a word line.

The gate structure 140 may be formed by an anisotropic etching process. For example, after forming a photoresist pattern on the control gate conductive layer, an RIE process may be performed using the photoresist pattern as an etching mask to form the gate structure 140.

In accordance with another example embodiment of the present invention, a mask pattern including oxide or nitride may be formed on the control gate conductive layer, and the gate structure 140 may be formed by an anisotropic etching process using the mask pattern.

Surface portions of the gate structure 140 and the substrate 100 may be damaged by the RIE process. For example, the RIE process may cause a large number of defect sites to be formed in the surface portions of the gate structure 140. In particular, the RIE process may cause silicon dangling bonds, such as unstable Si—O bonds and/or Si—H bonds, to be formed at edge portions of the tunnel insulating layer pattern 138. Electrons or holes may be trapped in such defect sites during programming and erasing operations of the associated non-volatile memory device, which may deteriorate the data retention performance and/or reliability of the non-volatile memory device.

Referring to FIG. 11, an oxidation process may be performed to at least partially cure the damage caused to the gate structure 140. It can be desirable for the oxidation process to be carried out without changing a thickness of the tunnel insulating layer pattern 138.

An oxide layer 142 having a thickness of about 40 Å may be formed on the gate structure 140 and the substrate 100 by the oxidation process.

The oxidation process may be at least partially performed using oxygen radicals (O*). For example, a radical oxidation process may be at least partially performed using a first reactive gas including oxygen (O₂) and hydrogen (H₂). The radical oxidation process may be at least partially performed using a batch-type or single-type oxidation apparatus including a plasma source. Examples of the plasma source may include a remote plasma generator using microwave energy, a modified-magnetron type (MMT) plasma generator using a radio frequency (RF) power source, etc.

Oxygen radicals (O*) or hydroxide radicals (OH*) may be generated by the plasma source. The radical oxidation process may be at least partially performed at one or more temperatures within a range between-about 800° C. to about 1,100° C. and under pressure within a range between about 1 mTorr to about 10 Torr. In particular, the radical oxidation process may be at least partially performed at one or more temperatures within a range between about 800° C. to about 950° C. For example, the radical oxidation process may be performed at a temperature of about 900° C.

Meanwhile, a flow rate of the hydrogen gas may be between about 10 percent to about 33 percent of a flow rate of the first reactive gas (i.e., the first reactive gas mixture including the hydrogen gas and oxygen gas).

In accordance with another example embodiment of the present invention, a dry oxidation process and/or a wet oxidation process may be performed to at least partially cure the damage to the gate structure 140. The dry oxidation process may be at least partially performed using oxygen (O₂) and/or ozone (O₃), and the wet oxidation process may be at least partially performed using water vapor (H₂O).

However, the defect sites of the gate structure 140 may not be sufficiently removed by the oxidation process alone. Accordingly, a first heat treatment and a second heat treatment may be sequentially performed to further remove the defect sites in the gate structure 140.

The first heat treatment may be at least partially performed under a gas atmosphere include nitrogen, and the second heat treatment may be at least partially performed under a gas atmosphere including oxygen and chlorine.

The first heat treatment may be at least partially performed under a gas atmosphere including nitrogen (N₂), nitrogen monoxide (NO), nitrous oxide (N₂O), and/or ammonia (NH₃). For example, the first heat treatment may be at least partially performed using a second reactive gas including nitrogen (N₂) and nitrogen monoxide (NO). In particular, a flow rate of the nitrogen monoxide gas may be about 1 percent to about 20 percent of a flow rate of the second reactive gas. For example, an amount of the second reactive gas used during the first heat treatment may be about 10 liters, and an amount of the nitrogen monoxide gas used during the first heat treatment may be about 0.3 liters.

The first heat treatment may be at least partially performed at one or more temperatures within a range between about 800° C. to about 1,100° C. and under pressure within a range between about 1 mTorr to about 10 Torr. In particular, the first heat treatment may be at least partially performed at one or more temperatures within a range between about 800° C. to about 950° C. For example, the first heat treatment may be performed at a temperature of about 900° C. Further, the oxidation process and the first heat treatment may be performed in-situ, such as without breaking vacuum seal of a chamber in which the processes are carried out.

The first heat treatment may be performed to at least partially remove the defect sites of the gate structure 140. The first heat treatment may at least partially remove silicon dangling bonds in the gate structure 140 and substitute silicon-nitrogen (Si—N) bonds for the existing unstable bonds. As a result, a concentration of nitrogen may be increased in an interface portion between the gate structure 140 and the oxide layer 142. As a further result, a silicon oxynitride layer including Si—N bonds may be formed between the gate structure 140 and the oxide layer 142, where the silicon oxynitride layer may serve as a barrier layer which inhibits/prevents an oxidizing agent from penetrating into the gate structure 140 during the subsequent second heat treatment.

The second heat treatment may be performed to further remove remaining defect sites of the gate structure 140 after the first heat treatment. The second heat treatment may be at least partially performed under a gas atmosphere including an oxidizing agent, such as oxygen (O₂), ozone (O₃), water vapor (H₂O), etc., and hydrogen chloride (HCl).

For example, the second heat treatment may be at least partially performed using a third reactive gas including oxygen (O₂) and hydrogen chloride (HCl). In particular, a flow rate of the hydrogen chloride gas may be about 0.1 percent to about 10 percent of a flow rate of the third reactive gas. For example, an amount of the third reactive gas used during the second heat treatment may be about 11 liters, and an amount of the hydrogen chloride gas used during the second heat treatment may be about 0.1 liters.

The second heat treatment may be at least partially performed at one or more temperatures within a range between about 800° C. to about 1,100° C. and under a pressure of about 1 mTorr to about 10 Torr. In particular, the second heat treatment may be at least partially performed at one or more temperatures within a range between about 800° C. to about 950° C. For example, the second heat treatment may be performed at a temperature of about 900° C. Further, the first and second heat treatments may be performed in-situ, such as without breaking vacuum seal of a chamber in which the processes are carried out.

The silicon oxynitride layer formed by the first heat treatment may inhibit/prevent the oxidizing agent from penetrating into the gate structure 140 during the second heat treatment. Thus, although a thickness of the oxide layer 142 may be a little increased during the second heat treatment, variation of thickness in the tunnel insulating layer pattern 138 may be sufficiently constrained. For example, the thickness of the oxide layer 142 may be increased by about 5 Å during the second heat treatment, but a variation of thickness at edge portions of the tunnel insulating layer pattern 138 may be constrained to no more than about 3 Å. As a result, a bird's beak may be inhibited/prevented from being formed at the edge portions of the tunnel insulating layer pattern 138, because edge portions of the floating gate electrode 136 may be sufficiently constrained from becoming oxidized.

Further, the remaining defect sites of the gate structure 140 may be sufficiently removed during the second heat treatment. In particular, existing unstable Si—H bonds may be substituted with stable silicon-chlorine (Si—Cl) bonds, and remaining silicon dangling bonds may be further reduced/removed.

After performing the second heat treatment, source/drain regions (not shown) may be formed at surface portions of the substrate 100 adjacent to the gate structure 140, thereby forming a non-volatile memory device on the semiconductor substrate 100. The source/drain regions may be formed by an ion implantation process and a heat treatment that electrically activates impurities implanted by the ion implantation process. Spacers may be formed on sidewalls of the gate structure 140 before forming the source/drain regions.

The gate structure 140 may be protected by the silicon oxynitride layer during the ion implantation process.

### Experimental Results of Non-Volatile Memory Device Reliability:

A first non-volatile memory device was manufactured by a conventional process. In particular, a first gate structure including a first control gate electrode, a first blocking layer pattern, a first floating gate electrode and a first tunnel insulating layer pattern were formed on a semiconductor substrate. A radical oxidation process and a heat treatment were sequentially performed to reduce etch damage to the first gate structure. The radical oxidation process was performed at a temperature of about 900° C. using a reactive gas including oxygen (O₂) and hydrogen (H₂). The heat treatment was performed at a temperature of about 900° C. using a reactive gas including nitrogen (N₂) and nitrogen monoxide (NO). An oxide layer having a thickness of about 45 Å was formed on the first gate structure and the semiconductor substrate by the radical oxidation process. First source/drain regions were formed at surface portions of the semiconductor substrate adjacent to the first gate structure.

A second non-volatile memory device was manufactured by methods according to an example embodiment of the present invention. In particular, a second gate structure including a second control gate electrode, a second blocking layer pattern, a second floating gate electrode and a second tunnel insulating layer pattern were formed on a semiconductor substrate. A radical oxidation process, a first heat treatment, and a second heat treatment were performed in-situ to at least partially cure etch damage and to at least partially remove defect sites on the second gate structure. The radical oxidation process was performed at a temperature of about 900° C. using a reactive gas including oxygen (O₂) and hydrogen (H₂). The first heat treatment was performed at a temperature of about 900° C. using a reactive gas including nitrogen (N₂) and nitrogen monoxide (NO). The second heat treatment was performed at a temperature of about 900° C. using a reactive including oxygen (O₂) and hydrogen chloride (HCl). An oxide layer having a thickness of about 40 Å was formed on the second gate structure and the semiconductor substrate by the radical oxidation process. The thickness of the oxide layer was increased by about 5 Å during the second heat treatment. Second source/drain regions were formed at surface portions of the semiconductor substrate adjacent to the second gate structure.

FIG. 12 is a graph illustrating high-temperature stress (HTS) characteristics that were determined by experimentation on the first non-volatile memory device manufactured by the conventional process and experimentation on the second non-volatile memory device manufactured by methods according to the example embodiment of the present invention.

The illustrated HTS characteristics were determined by repeatedly carrying out programming and erasing operations of the first and second non-volatile memory devices 1,200 times, and then measuring threshold voltages of the first and second non-volatile memory devices. Baking processes on the programmed first and second non-volatile memory devices were performed at a temperature of about 200° C. for about 2 hours, and then threshold voltages of the first and second non-volatile memory devices were measured.

Referring to FIG. 12, a variation of the threshold voltage in the first non-volatile memory device was measured at about 0.6 V, and a variation of the threshold voltage in the second non-volatile memory device was measured at about 0.52 V. As a result, it appears that the HTS characteristics of the second non-volatile memory device were improved by about 0.08 V compared to the first non-volatile memory device.

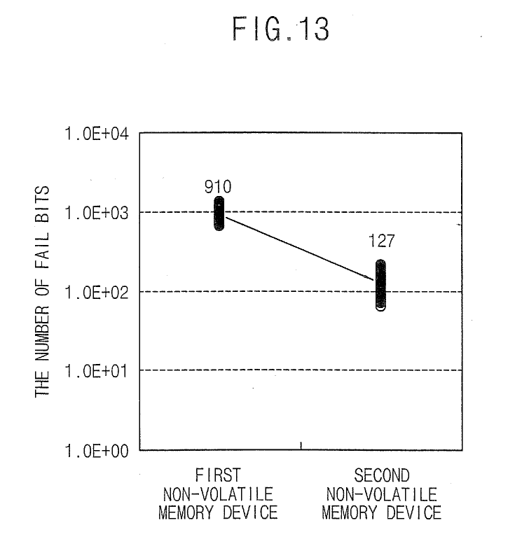

FIG. 13 is a graph illustrating read disturbances that were determined by experimentation on the first non-volatile memory device manufactured by the conventional process and experimentation on the second non-volatile memory device manufactured by the methods according to the example embodiment of the present invention.

Programming and erasing operations of the first and second non-volatile memory devices were repeatedly performed 1,200 times, and then a reading voltage of about 6 V was repeatedly applied to the first and second gate structures about 100,000 times. The number of failed bits in each of the first and second non-volatile memory devices was measured. Moreover, the number of cells programmed by applying the reading voltage in the first and second non-volatile memory devices was measured.

Referring to FIG. 13, about 910 failed bits occurred in the first non-volatile memory device, and about 127 failed bits occurred in the second non-volatile memory device. Accordingly, it appears that the read disturbance of the second non-volatile memory device was remarkably reduced compared to the first non-volatile memory device.

Although not shown in the figures, variation of thickness at edge portions of the first tunnel insulating layer pattern was measured at about 6 Å to about 9 Å, and variation of thickness at edge portions of the second tunnel insulating layer pattern was measured at about 2 Å to about 3 Å.

In accordance with various example embodiments of the present invention described above, defect sites in a gate structure of a non-volatile memory device may be sufficiently reduced/removed by a radical oxidation process, a first heat treatment performed under a gas atmosphere including nitrogen, and a second heat treatment performed under a gas atmosphere including chlorine to improve operation of the related nonvolatile memory device. Further, variation of thickness in a tunnel insulating layer may be sufficiently constrained to avoid formation of a bird's beak therein. As a consequence, the data retention performance and/or reliability of the non-volatile memory device may be improved.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. The invention is defined by the following claims, with equivalents of the claims to be included therein.

What is claimed is:

1. A method of manufacturing a non-volatile memory device, the method comprising:
forming a gate structure on a substrate, the gate structure including a control gate electrode, a blocking layer pattern, a floating gate electrode, and a tunnel insulating layer pattern;
performing an oxidation process that at least partially cures damage caused to the substrate and to the gate structure during formation of the gate structure;
performing a first heat treatment under a gas atmosphere including nitrogen to at least partially remove defect sites on the gate structure caused by the oxidation process; and
performing a second heat treatment under a gas atmosphere including chlorine to at least partially remove remaining defect sites on the gate structure caused by the oxidation process.

2. The method of claim 1, wherein the oxidation process is at least partially performed using oxygen radicals.

3. The method of claim 2, wherein the oxidation process is at least partially performed at one or more temperatures within a range between about 800° C. to about 1,100° C.

4. The method of claim 1, wherein the oxidation process is at least partially performed using a reactive gas including oxygen (O₂) and hydrogen (H₂).

5. The method of claim 4, wherein a flow rate of the hydrogen (H₂) during the oxidation process is between about 10 percent to about 33 percent of a flow rate of the reactive gas.

6. The method of claim 1, wherein the oxidation process is at least partially performed using at least one selected from the group consisting of oxygen (O₂), ozone (O₃), and water vapor (H₂O).

7. The method of claim 1, wherein the first heat treatment is at least partially performed under a gas atmosphere including at least one selected from the group consisting of nitrogen (N₂), nitrogen monoxide (NO), nitrous oxide (N₂O), and ammonia (NH₃).

8. The method of claim 7, wherein the first heat treatment is at least partially carried out using a reactive gas including nitrogen (N2) and nitrogen monoxide (NO).

9. The method of claim 8, wherein a flow rate of the nitrogen monoxide (NO) during the first heat treatment is about 1 percent to about 20 percent of a flow rate of the reactive gas.

10. The method of claim 1, wherein the first heat treatment is at least partially performed at one or more temperatures within a range between about 800° C. to about 1,100° C.

11. The method of claim 1, wherein the second heat treatment is at least partially performed under a gas atmosphere including hydrogen chloride (HCl) and at least one selected from the group consisting of oxygen (O₂), ozone (O₃), and water vapor (H₂O).

12. The method of claim 11, wherein the second heat treatment is at least partially performed using a reactive gas including hydrogen chloride (HCl) and oxygen (O₂).

13. The method of claim 12, wherein a flow rate of the hydrogen chloride (HCl) is about 0.1 percent to about 10 percent of a flow rate of the reactive gas.

14. The method of claim 1, wherein the second heat treatment is at least partially performed at one or more temperatures within a range between about 800° C. to about 1,100° C.

15. The method of claim 1, wherein the oxidation process and the first heat treatment are performed in-situ within a chamber without breaking vacuum seal of the chamber.

16. The method of claim 1, wherein the first and second heat treatments are performed in-situ within a chamber without breaking vacuum seal of the chamber.

17. The method of claim 1, wherein the oxidation process and the first and second heat treatments are performed in-situ within a chamber without breaking vacuum seal of the chamber.

18. The method of claim 1, wherein the blocking layer pattern is formed to include a lower dielectric layer, a middle dielectric layer, and an upper dielectric layer.

19. The method of claim 18, wherein each of the lower and upper dielectric layers are formed to include silicon oxide, and the middle dielectric layer is formed to include silicon nitride or to include metal oxide having a dielectric constant higher than that of silicon nitride.

20. The method of claim 19, wherein the metal oxide includes at least one selected from the group consisting of hafnium (Hp, zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).
